(19) United States
(12) Patent Application Publication
(10) Pub. No.: US 2026/0139371 A1
(43) Pub. Date: May 21, 2026

(54) SUBSTRATE PROCESSING APPARATUS

(71) Applicant: ASM IP Holding B.V., Almere (NL)

(72) Inventors: Vincent Vandalon, Heverlee (BE); Kenneth Honniball, Kessel-Lo (BE)

(21) Appl. No.: 19/389,276

(22) Filed: Nov. 14, 2025

Related U.S. Application Data
(60) Provisional application No. 63/722,433, filed on Nov. 19, 2024.

(51) Int. Cl. C23C 16/44; C23C 16/52

(52) U.S. Cl. CPC C23C 16/4412; C23C 16/52

(57) ABSTRACT

A substrate processing apparatus with ballast gas function is presented. The substrate processing apparatus according to the present disclosure comprises a chamber wall defines a processing space for processing the substrate, an exhaust port configured to let a gas out of the processing space, an exhaust gas line disposed from the exhaust port at a predetermined length, configured to expedite the gas from the substrate processing apparatus, a throttle valve disposed in the exhaust gas line for controlling an exhausting flow of the gas, and a ballast unit fluidly connected to the exhaust gas line and configured to inject a ballast gas to the exhaust gas line.

### CROSS-REFERENCE TO RELATED APPLICATIONS

This application claims priority to U.S. Provisional Patent Application Ser. No. 63/722,433, filed Nov. 19, 2024 and titled SUBSTRATE PROCESSING APPARATUS, the disclosure of which is hereby incorporated by reference in its entirety.

### FIELD OF INVENTION

The present disclosure relates generally to a substrate processing apparatus, more particularly to a substrate processing apparatus equipped with ballast gas injection for increasing the lifetime of a throttle valve in an exhaust line of the substrate processing apparatus.

### BACKGROUND OF THE DISCLOSURE

When a substrate processing apparatus is operational, a throttle valve in an chamber exhaust line moves to a more closed state in order to keep the chamber pressure at a preset point. In certain cases, the throttle valve is in an almost closed state.

As illustrated in FIG. 1, a sealing surface of a throttle valve 101 on a valve edge 131 and even an inner wall 130 of an exhaust line 140 may build up an unwanted deposited layer during substrate deposition operation. If the unwanted deposited layer gets large or hard, the rotation of the throttle valve 101 may become more difficult with an extended radius of the throttle valve 101 (depicted by a circle 120). Before the deposit on the valve edge 131, the rotation would be easier (depicted by a circle 110). Throttle valve replacement may be required to avoid this case.

Therefore, a method to extend the lifetime of the throttle valve may be needed and the present disclosure provides a substrate processing apparatus structure which can achieve the purpose described above.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a substrate processing apparatus comprises: a chamber wall defines a processing space for processing the substrate; an exhaust port configured to let a gas out of the processing space; an exhaust gas line disposed from the exhaust port at a predetermined length, configured to expedite the gas from the substrate processing apparatus; a throttle valve disposed in the exhaust gas line for controlling an exhausting flow of the gas; and a ballast unit fluidly connected to the exhaust gas line and configured to inject a ballast gas to the exhaust gas line.

In an aspect, the ballast unit further comprising, a gas supply configured to contain and supply a ballast gas; a filter fluidly connected to the gas supply and configured to filter the ballast gas from the gas supply; and a controller connected to the filter and configured to control a flow of the ballast gas into the exhaust gas line.

In an aspect, the ballast gas is one of nitrogen gas (N₂), argon gas (Ar), or helium gas (He).

In an aspect, the ballast unit is connected to a first position of the exhaust gas line, wherein the first position is located between a starting point of the exhaust gas line and the throttle valve.

In an aspect, the ballast unit is connected to a second position of the exhaust gas line, wherein the second position is located between the throttle valve and an ending point of the exhaust gas line.

In an aspect, the controller is a mass flow controller (MFC).

In an aspect, the throttle valve has a predetermined open value during substrate processing.

In an aspect, the predetermined open value is a number between zero (0) and 100, wherein the number is above zero (0).

In an aspect, the exhaust gas line is further configured to be disposed along the chamber wall vertically.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates depositions buildup on throttle valve's sealing edge and on exhaust gas line's inner wall.

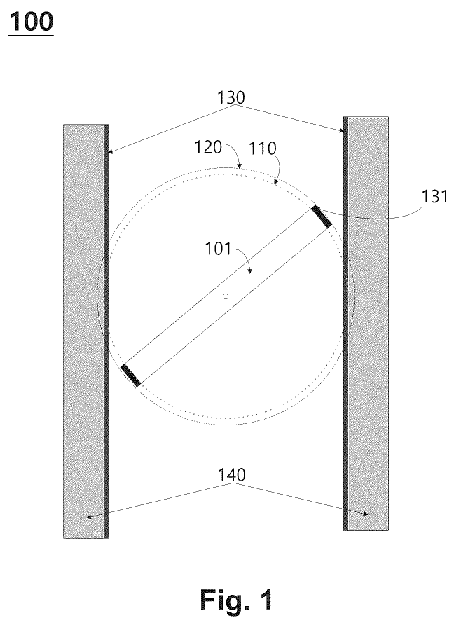

FIG. 2 illustrates a side view of a substrate processing apparatus according to an embodiment of the present disclosure.

FIG. 3 illustrates how a throttle valve may close or open the exhaust gas line.

FIG. 4 illustrates the structure of the ballast unit according to an embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

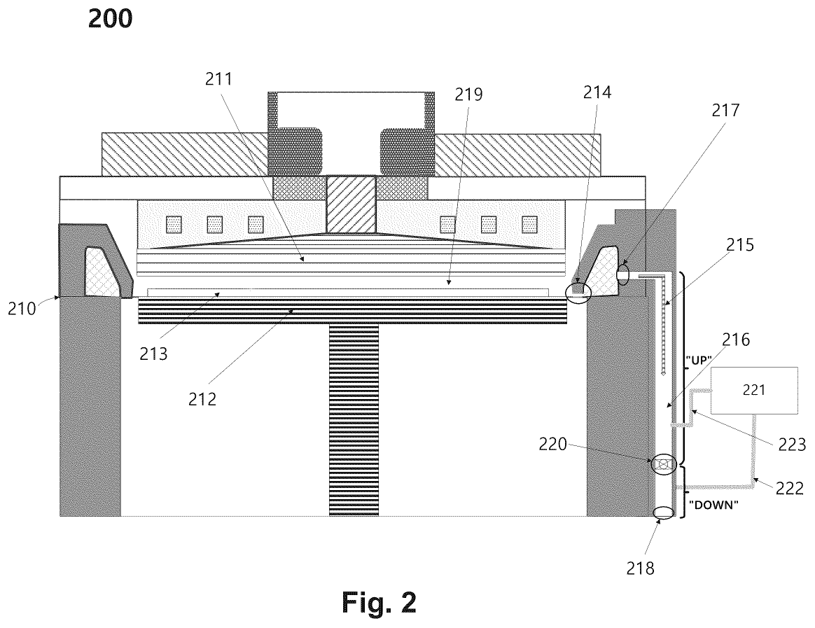

FIG. 2 illustrates a substrate processing apparatus 200 according to an embodiment of the present disclosure.

The substrate processing apparatus 200 may comprise a susceptor 212, a chamber wall 210, a showerhead 211, an exhaust port 214, an exhaust gas line 216 and a throttle valve 220. The susceptor 212 may be equipped with a heater to heat and support a substrate 213 placed on it. The substrate processing apparatus 200 may be configured to have the chamber wall 210 encompassing the susceptor 212.

The showerhead 211 may be disposed above the susceptor 212 such that the susceptor 212, the showerhead 211 and the chamber wall 210 may form a processing space 219 for processing the substrate 213.

The exhaust port 214 may be disposed in an edge area of the processing space 219 and may be used to pump out the gas and plasma from the processing space 219. The gas 215 pumped out from the processing space 219 may flow through the exhaust gas line 216. To control the pressure in the processing space 219 during substrate process according to a recipe, a throttle valve 220 may be disposed in the exhaust gas line 216. The exhaust gas line 216 may be configured to be disposed along the chamber wall 210 vertically.

To extend the lifetime of the throttle valve 220 by providing a ballast gas, a ballast unit 221 may be configured to fluidly be connected to the exhaust gas line 216 and to inject a ballast gas to the exhaust gas line 216.

The connection position of the exhaust gas line 216 and the ballast unit 221 would be either 1) in a region (“UP”) located between the staring position 217 and the throttle valve 220, or 2) in a region (“DOWN”) located between the throttle valve 220 and the ending position 218. The connecting line 223 may connect the ballast unit 221 to the “UP” region while the connecting line 222 may connect the ballast unit 221 to the “DOWN” region.

It is obvious that FIG. 2 is presented as an example and many other apparatus embodiments may be possible such as a vertical furnace and/or an apparatus with remote plasma unit (RPU) which do not need susceptor support and/or showerhead.

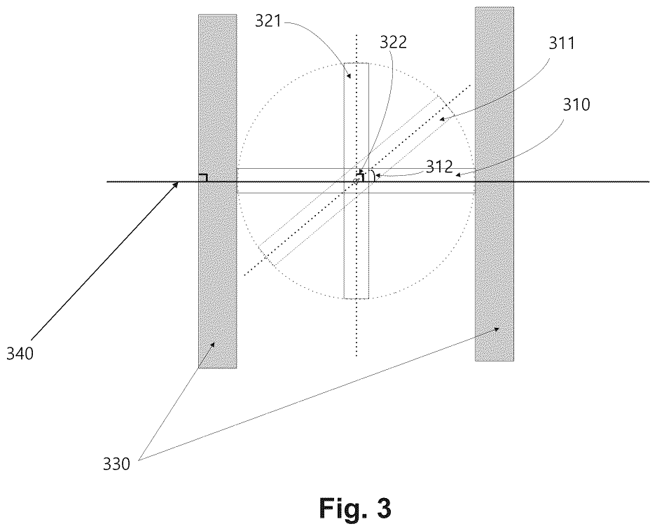

FIG. 3 illustrates how a throttle valve may close or open in the exhaust gas line.

A throttle valve 310 may be disposed in an exhaust gas line 330. The throttle valve 310 may close the exhaust gas line 330 completely when it is aligned with a cross-line 340 and the cross-line 340 may be an imaginary line perpendicular to the exhaust gas line 330.

An ‘open value’ may be used for measuring a degree of openness of the throttle valve 310 in relation to the exhaust gas line 330. A complete open of the throttle valve like the throttle valve 321 has an open value of 100 and a complete close of the throttle valve like the throttle valve 310 has an open value of 0 (zero).

An open value of a throttle valve may be measured by the angle between the throttle valve 310 and the cross-line 340. Open value of ‘100’ means that the throttle valve 321 is at a 90 degrees angle from the cross-line 340 and open value of ‘0’ (zero) means 0 that the throttle valve 310 is at a 0 degree angle from the cross-line 340. Since open value 100 means 90 degrees angle, open value of 1 means 0.9 degree.

For a specific recipe, the open value of a throttle valve during the recipe operation may be controlled and changed. When the open value is 0 (zero), this means an increased risk of throttle valve failure and the throttle valve 310 may get physically stuck with the exhaust gas line 330 as a result.

To avoid this danger, the open value of the throttle valve 311 during a recipe operation may be any arbitrary number between 1 and 100. It should be noted that the open value should be above zero (0) to avoid throttle failure. The open value may be between 10 and 30. Open value between 10 and 30 means the throttle valve 311 never closes the exhaust gas line 330 fully and positions at 9 degrees to 27 degrees angle from the cross-line 340. This

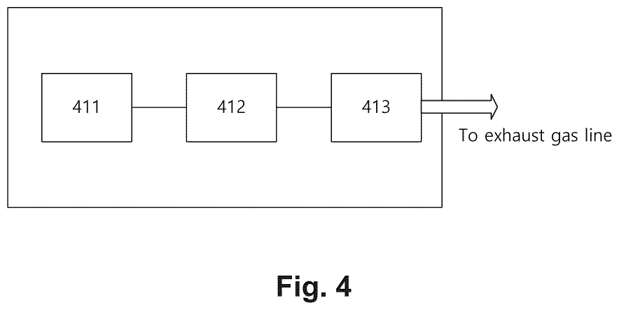

FIG. 4 illustrates the structure of the ballast unit 221. The ballast unit 221 may comprise a gas supply 411, a filter 412, and a controller 413.

The gas supply 411 may be configured to contain and supply a ballast gas. The ballast gas to be injected into the exhaust gas line 216 may be one of an inert gas, such as nitrogen gas (N₂), helium gas (He) or argon gas (Ar). By injecting a ballast gas into the exhaust gas line 216, the unwanted deposition buildup on the throttle valve edge 131 and the inner chamber wall 130 is decreased and this may extend the lifetime of the throttle valve.

The filter 412 may be fluidly connected to the gas supply 411 and be configured to filter the ballast gas from the gas supply 411. The controller 413 may be fluidly connected to the filter 412 and configured to control a flow of the ballast gas into the exhaust gas line 216. The controller 413 may be a mass flow controller (MFC) to control the gas flow more efficiently.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A substrate processing apparatus comprises:
a chamber wall defines a processing space for processing the substrate;
an exhaust port configured to let a gas out of the processing space;
an exhaust gas line disposed from the exhaust port at a predetermined length, configured to expedite the gas from the substrate processing apparatus;
a throttle valve disposed in the exhaust gas line for controlling an exhausting flow of the gas; and
a ballast unit fluidly connected to the exhaust gas line and configured to inject a ballast gas to the exhaust gas line.

2. The substrate processing apparatus according to claim 1, the ballast unit further comprising:
a gas supply configured to contain and supply the ballast gas;
a filter fluidly connected to the gas supply and configured to filter the ballast gas from the gas supply; and
a controller connected to the filter and configured to control the ballast gas into the exhaust gas line.

3. The substrate processing apparatus according to claim 2, wherein the ballast gas is one of nitrogen (N₂), argon (Ar), or helium (He).

4. The substrate processing apparatus according to claim 1, wherein the ballast unit is connected to a first position of the exhaust gas line, wherein the first position is located between a starting point of the exhaust gas line and the throttle valve.

5. The substrate processing apparatus according to claim 1, wherein the ballast unit is connected to a second position of the exhaust gas line, wherein the second position is located between the throttle valve and an ending point of the exhaust gas line.

6. The substrate processing apparatus according to claim 2, wherein the controller comprises a mass flow controller (MFC).

7. The substrate processing apparatus according to claim 1, wherein the throttle valve has a predetermined open value during substrate processing.

8. The substrate processing apparatus according to claim 7, wherein the predetermined open value is a number between zero (0) and 100, wherein the number is above zero (0).

9. The substrate processing apparatus according to claim 1, wherein the exhaust gas line is further configured to be disposed along the chamber wall vertically.
